(19) United States
(12) Patent Application Publication
(10) Pub. No.: US 2008/0073772 A1
(43) Pub. Date: Mar. 27, 2008

(54) STACKED SEMICONDUCTOR PACKAGE AND METHOD OF MANUFACTURING THE SAME

(75) Inventors: Sun-Pil YOUN, Seoul (KR); Jong-Woo KO, Gyeonggi-do (KR); Jeong-Jin LEE, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggid-do (KR)

(21) Appl. No.: 11/555,155

(22) Filed: Oct. 31, 2006

(30) Foreign Application Priority Data
Sep. 21, 2006 (KR) 2006-0091792

(51) Int. Cl. H01L 23/48

(52) U.S. Cl. 257/690

(57) ABSTRACT

Provided are highly reliable, high density stacked semiconductor packages including a plurality of semiconductor chips and a method of manufacturing the highly reliable, high density semiconductor package. An embodiment of the stacked semiconductor package includes upper and lower semiconductor packages that are sequentially stacked. The upper and lower semiconductor packages include inner leads connected to semiconductor chips. The lower semiconductor package may further include a plurality of outer leads connected to the inner leads of the lower semiconductor package and that extend outside a encapsulant to be electrically connected to the inner leads of the upper semiconductor package.

### CROSS-REFERENCE TO RELATED PATENT APPLICATION

This application claims the benefit of Korean Patent Application No. 10-2006-0091792, filed on Sep. 21, 2006, in the Korean Intellectual Property Office, the disclosure of which is incorporated by reference.

### BACKGROUND

1. Field of the Invention

The present invention relates to a semiconductor package, and more particularly, to a stacked semiconductor package and a method of manufacturing the same.

2. Description of the Related Art

Assembling technology for manufacturing semiconductor packages has been rapidly developing with the recent advancements in semiconductor device technology. In particular, the size of semiconductor packages has continued to be reduced to match the demand for compact and light products that contain such semiconductor packages. Typically, these semiconductor products require high capacity semiconductor packages to fulfill the technological requirements of the products. Thus, stacked semiconductor packages or a multi-chip semiconductor packages including a plurality of semiconductor chips are often used.

However, conventional stacked semiconductor packages are limited in general terms of thickness due to the necessary thickness of the encapsulant enclosing semiconductor chips in upper and lower semiconductor packages for protection. Also, the leads of each of the upper and lower semiconductor packages generally protrude underneath the encapsulant. Thus, the thickness of the general stacked semiconductor package may be further increased.

To address these problems, a method of forming leads of a semiconductor package to be parallel with a encapsulant has been suggested. However, these suggested stack structures of such semiconductor packages have reliability problems relating to the electrical connection between the leads of upper and lower semiconductor packages. For example, the contact area between leads may be small, and particles may be interposed between the leads during manufacturing or use, which degrades the electrical connections. Furthermore, in these suggested stack structures of the upper and lower semiconductor packages, the leads are generally formed using half etching. However, this leads to another problem because of the necessary etching depth required by half etching. In particular, as a result of the typical required etching depth, the stacked semiconductor package may be difficult to integrate in a compact multi-chip package that includes a plurality of semiconductor chips.

### SUMMARY

The present invention provides a highly reliable, high density stacked semiconductor package including a plurality of semiconductor chips, and further provides a method of manufacturing such highly reliable, high density stacked semiconductor package.

According to an embodiment of the present invention a stacked semiconductor package may include sequentially stacked upper and lower semiconductor packages, each having at least one semiconductor chip, a plurality of inner leads connected to the chips, and a encapsulant covering the chips and the inner leads. Additionally, the lower semiconductor package may include a plurality of outer leads connected to the inner leads that extend outside the encapsulant to be electrically connected to the inner leads of the lower semiconductor package.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a stacked semiconductor package according to an embodiment of the present invention;

FIG. 2 is a cross-sectional view of a stacked semiconductor package according to another embodiment of the present invention;

FIG. 3 is a cross-sectional view of a stacked semiconductor package according to another embodiment of the present invention;

FIG. 4 is a cross-sectional view of a stacked semiconductor package according to another embodiment of the present invention;

FIG. 5 is a cross-sectional view of a stacked semiconductor package according to another embodiment of the present invention; and

FIG. 6 is a cross-sectional view of a stacked semiconductor package according to another embodiment of the present invention.

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity.

In the embodiments of the present invention, a stacked semiconductor package may refer to a structure in which at least one or more pairs of semiconductor packages are stacked and electrically connected to each other. Also, inner leads and outer leads are defined separately. The inner leads refer to leads or lead frame parts including surfaces attached to and fixed to an encapsulant, and the outer leads refer to leads or lead frame parts extending outside the encapsulant. The inner and outer leads may refer to a structure body that is virtually divided into inner and outer leads physically connected to one another. Thus, in the embodiments of the present invention, a semiconductor package may include only inner leads or may include inner leads and outer leads.

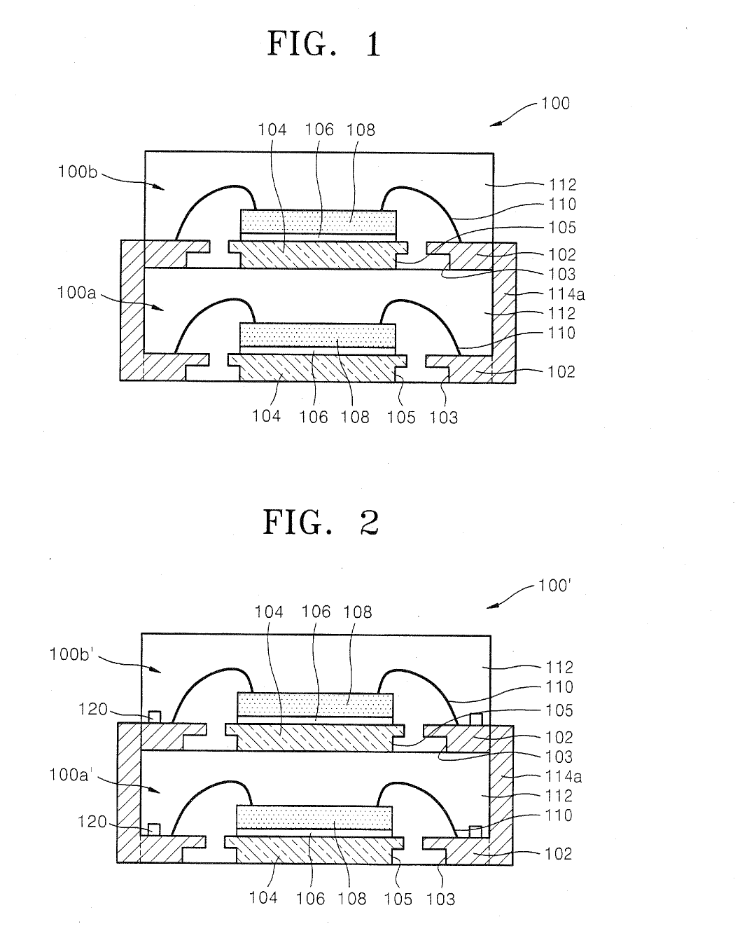

FIG. 1 is a cross-sectional view of a stacked semiconductor package 100 according to an embodiment of the present invention. Referring to FIG. 1, the stacked semiconductor package 100 includes an upper semiconductor package 100b and a lower semiconductor package 100a that are sequentially stacked. The lower and upper semiconductor packages 100a and 100b respectively include semiconductor chips 108 which are fixed and protected by encapsulant 112. The semiconductor chips 108 may be attached to chip mounting pads 104 using adhesive members 106. The semiconductor chips 108 may include memory devices and/or logic devices. However, the present invention is not limited to these types of devices. Further, the semiconductor chips 108 of the lower and upper semiconductor packages 100a and 100b do not necessarily need to be similar to each other.

The encapsulant 112 protects the semiconductor chips 108 from the external environment and may include a molding resin having epoxy compounds. Although encapsulant 112 is discussed throughout these embodiments in a singular form, the encapsulant may encompass separate and distinct sections of resin material that may or may not be in contact with each other. Thus, the term encapsulant may include one or more portions of encapsulant or resin material. Alternatively, the encapsulant may be formed of a material other than resin. For example, the encapsulant may be formed using a ceramic material. The chip mounting pads 104 may also include notches 105 at their edges to help increase the bond strength between the chip mounting pads 104 and the encapsulant 112. Edge portions of the chip mounting pads 104 may further protrude toward the encapsulant 112 due to the notches 105 and may thus also be fixed by the encapsulant 112. However, the bottom surfaces of the chip mounting pads 104 may be exposed from the encapsulant 112. In a modification of the present embodiment, holes (not shown) may be formed at the chip mounting pads 104 instead of the notches 105 or may be formed together with the notches 105 at the chip mounting pads 104.

A plurality of inner leads 102 may respectively be electrically connected to the semiconductor chips 108 through wires 10 and may further be encompassed or encapsulated by the encapsulant 112. The inner leads 102 may include upper surfaces to which the wires 110 are connected and bottom surfaces opposite the upper surfaces. The upper surfaces of the inner leads 102 may be attached to and fixed to the encapsulant 112. At least portions of the bottom surfaces of the inner leads 102 may be exposed from the encapsulant 112. In addition, sides of the inner leads 102 may be exposed from the encapsulant 112. The exposed portions of the inner leads 102 may be used as portions connected to another semiconductor package in a stack structure or operate as external terminals. The lower and upper semiconductor packages 100a and 100b may be referred to as exposed lead packages (ELPs) due to the structures of inner leads 102 and/or the chip mounting pads 104. However, the scope of the present invention is not limited to this name.

The inner leads 102 may also include notches 103 to increase the bond strength between the inner leads 102 and the encapsulant 112. As shown in FIG. 1, edge portions of the inner leads 102 may protrude inward over a portion of the encapsulant 112 due to the notches 103, which may increase the bond strength between the inner leads 102 and the encapsulant 112. In a modification of the present embodiment, the inner leads 102 may include holes (not shown) instead of the notches 103 or may include the holes along with the notches 103 to increase the bond strength with the encapsulant 112. The notches 103 or the holes may be formed using a half etching method and filled with the encapsulant 112.

In another modification of the present embodiment, the chip mounting pads 104 may be omitted, and thus the semiconductor chips 108 may be disposed directly on the inner leads 102 so as to be electrically connected to the inner leads 102. This structure may be called a lead on chip (LOC) structure. Again, the scope of the present invention is not limited to this name.

The lower semiconductor package 100a may further include a plurality of outer leads 114a. The outer leads 114a may be connected to the inner leads 102 and extend outside the area that the encapsulant 112 encapsulates or encompasses. For example, the outer leads 114a may be physically connected to the inner leads 102 and formed in an upward maimer, i.e., toward the upper semiconductor package 100b. The outer leads 114a may further be electrically connected to the inner leads 102 of the upper semiconductor package 100b; thus resulting in the inner leads 102 of the lower semiconductor package 100a being electrically connected to the inner leads 102 of the upper semiconductor package 100b.

For example, edge portions of the outer leads 114a may be soldered to the sidewalls of the inner leads 102 of the upper semiconductor package 100b. In the present embodiment, the outer leads 114a may also be bent upward from the inner leads 102 of the lower semiconductor package 100a. Thus, the inner leads 102 of the upper semiconductor package 100b may be placed on the encapsulant 112 of the lower semiconductor package 100a. In other words, the outer leads 114a may not be interposed between the encapsulant 112 of the lower and upper semiconductor packages 100a and 100b but may be disposed outside the encapsulant 112 of both the lower and upper semiconductor packages 100a and 100b so as to reduce the height and volume of the stacked semiconductor package 100.

Furthermore, since the outer leads 114a may be bent using a forming method rather than a half etching method, the necessary dimensions of the outer leads 114a and the entire stacked semiconductor package 100 may be reduced. Further, a plurality of other semiconductor chips (not shown) may be stacked on the semiconductor chips 108 of the lower and upper semiconductor packages 100a and 100b. As a result, the lower and upper semiconductor packages 100a and 100b may be easily modified into multi-chip packages.

When the stacked semiconductor package 100 is mounted on a circuit board (not shown), the edge portions of the outer leads 114a and the inner leads 102 of the lower semiconductor package 100a may contact wiring lines of the circuit board. As a result, the contact area between the stacked semiconductor package 11 and the circuit board (now shown) may be increased, which in turn may improve the reliability of the electrical connection between the stacked semiconductor package 100 and the circuit board (now shown).

Although the above embodiment has been described with reference to only an upper and lower semiconductor package 100a and 100b, the stacked semiconductor package 100 may include a plurality of other semiconductor packages (not shown) that are further stacked on the upper and lower semiconductor packages 100a and 100b, and electrically connected to them.

FIG. 2 is a cross-sectional view of a stacked semiconductor package 100′ according to another embodiment of the present invention. The stacked semiconductor package 100′ is similar to the stacked semiconductor package 100 shown in FIG. 1, except for the presence of additional components. Thus, repeated descriptions of similar elements present in both embodiments will be omitted so that the differences between the two embodiments can be more clearly described.

Referring to FIG. 2, the stacked semiconductor package 100′ includes an upper semiconductor package 100b′ and a lower semiconductor package 100a′, which are sequentially stacked. The lower and upper semiconductor packages 100a′ and 100b′ may respectively correspond to the lower and upper semiconductor packages 100a and 100b shown in FIG. 1.

However, the lower and upper semiconductor packages 100a′ and 100b′ may further include nonconductive intermediate members 120.

The intermediate members 120 may be interposed between upper surfaces of inner leads 102 and encapsulant 112. The intermediate members 120 may extend across at least portions of the inner leads 102 to increase bond strength between the encapsulant 112 and the inner leads 102. For example, the intermediate members 120 may extend across upper surfaces of the inner leads 102 and have bar shapes. In the present embodiment, the intermediate members 120 are shown with notches 105 and 103. However, the intermediate members 120 or the notches 105 and 103 may be omitted or may be replaced with other appropriate members.

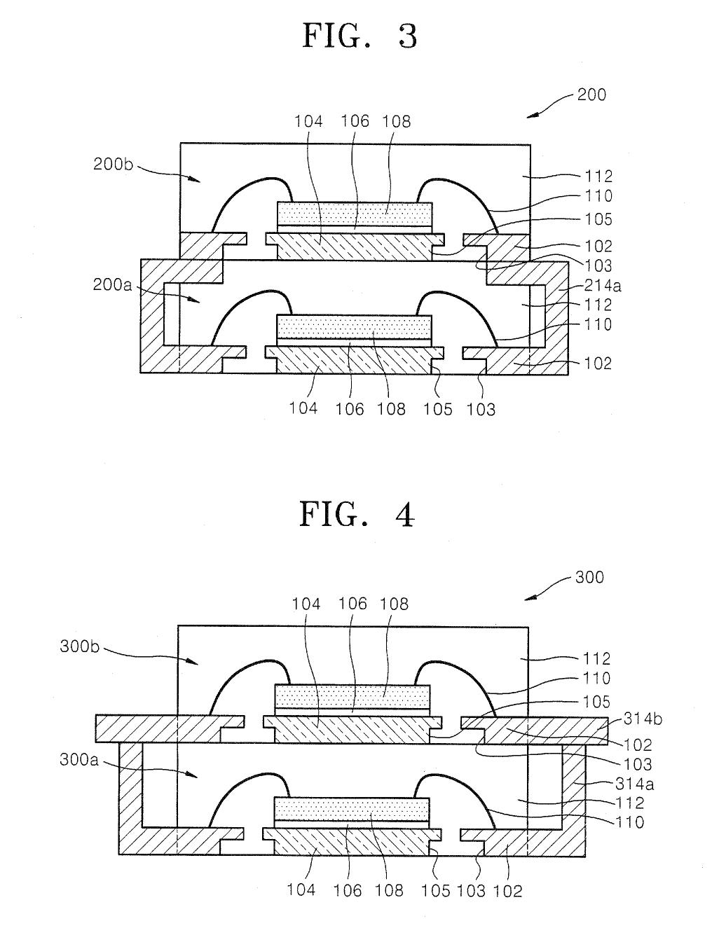

FIG. 3 is a cross-sectional view of a stacked semiconductor package 200 according to another embodiment of the present invention. The stacked semiconductor package 200 is similar to the stacked semiconductor package 100 shown in FIG. 1 except for the shapes and connection method of outer leads. Thus, repeated descriptions of similar elements present in both embodiments will be omitted so that the differences between the two embodiments can be more clearly described.

Referring to FIG. 3, the stacked semiconductor package 200 includes an upper semiconductor package 200b and a lower semiconductor package 200a, which are sequentially stacked. The lower and upper semiconductor packages 200a and 200b may respectively correspond to the lower and upper semiconductor packages 100a and 100b shown in FIG. 1. However, outer leads 214a of the lower semiconductor package 200a may be electrically connected to bottom portions of inner leads 102 of the tipper semiconductor package 200b. For example, edge portions of the outer leads 214a may be soldered to and electrically connected to the bottom portions of the inner leads 102 of the upper semiconductor package 200b.

For example, the outer leads 214a may be bent two times, and the edge portions of the outer leads 214a may be parallel with a direction along which the inner leads 102 extend. In other words, the outer leads 214a may extend from the inner leads 102 of the lower semiconductor package 200a, be bent upward, and bent at their edge portions to be parallel with the inner leads 102.

To facilitate this arrangement, the encapsulant 112 of the lower semiconductor package 200a under the edge portions of the outer leads 214a may be recessed. Thus, the edge portions of the outer leads 214a may be interposed between the inner leads 102 of the upper semiconductor package 200b and the encapsulant 112 of the lower semiconductor package 200a. Such a stack structure may contribute to reducing the height of the stacked semiconductor package 200 so as to inhibit further volume increases and improve package density.

In a modification of this embodiment, the lower and upper semiconductor packages 200a and 200b may include the intermediate members 120 of the lower and upper semiconductor packages 100a′ and 100b′ shown in FIG. 2.

FIG. 4 is a cross-sectional view of a stacked semiconductor package 300 according to another embodiment of the present invention. The stacked semiconductor package 300 is similar to the stacked semiconductor package 100 shown in FIG. 1, except for the shapes and connection method of outer leads. Thus, repeated descriptions of elements present in both embodiments will be omitted so that the differences between the two embodiments can be more clearly described.

Referring to FIG. 4, the stacked semiconductor package 300 includes an upper semiconductor package 300b and a lower semiconductor package 300a, which are sequentially stacked. The lower and upper semiconductor packages 300a and 300b may respectively correspond to the lower and upper semiconductor packages 100a and 100b shown in FIG. 1. However, outer leads 314a of the lower semiconductor package 300a have a different shape from the outer leads 114a shown in FIG. 1. Furthermore, the upper semiconductor package 300b may include a plurality of outer leads 314b.

In particular, the outer leads 314b of the upper semiconductor package 300b are connected to inner leads 102 of the upper semiconductor package 300b and extend outside the encapsulant 112. For example, the outer leads 314b may linearly extend from the inner leads 102 of the upper semiconductor package 300b. Additionally, the outer leads 314b may be physically connected to the inner leads 102 of the upper semiconductor package 300b.

The outer leads 314a of the lower semiconductor package 300a may be formed upward, i.e., toward the upper semiconductor package 300b, and edge portions of the outer leads 314a may be electrically connected to outer leads 314b. For example, the edge portions of the outer leads 314b may be disposed perpendicular to the outer leads 314a. For example, the outer leads 314a may linearly extend from the inner leads 102 of the lower semiconductor package 300a and then be bent upward. In addition, the outer leads 314a of the lower semiconductor package 300a may be soldered to the outer leads 314b of the upper semiconductor package 300b to facilitate the electrical connection between the outer leads 314a and 314b.

The stacked semiconductor package 300 may have similar advantages to the stacked semiconductor package 100 shown in FIG. 1. However, when the stacked semiconductor package 300 is mounted on a circuit board, the stacked semiconductor package 300 may have a lower contact resistance and a higher connection reliability than the stacked semiconductor package 100 shown in FIG. 1 in part because on increased contact areas. In other words, in the stacked semiconductor package 300, areas of the outer leads 314a and the inner leads 102 of the lower semiconductor package 300a electrically contacting the circuit board are comparatively wide.

In a modification of the above embodiment, the lower and upper semiconductor packages 300a and 300b may include the intermediate members 120 of the lower and upper semiconductor packages 100a′ and 100b′ shown in FIG. 2.

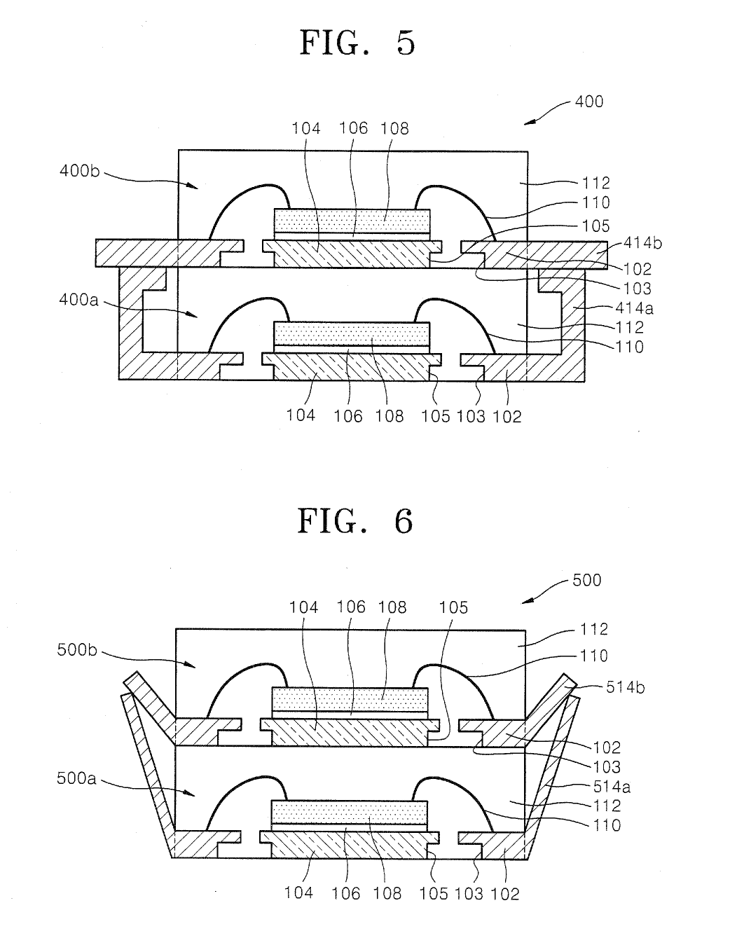

FIG. 5 is a cross-sectional view of a stacked semiconductor package 400 according to another embodiment of the present invention. The stacked semiconductor package 400 is similar to the stacked semiconductor package 300 shown in FIG. 4, except for the shapes and connection method of outer leads. Thus, repeated descriptions of similar elements present in both embodiments will be omitted so that differences between the two embodiments can be more clearly described.

Referring to FIG. 5, the stacked semiconductor package 400 includes an upper semiconductor package 400b and a lower semiconductor package 400a, which are sequentially stacked. The lower and upper semiconductor packages 400a and 400b may respectively correspond to the lower and upper semiconductor packages 300a and 300b shown in FIG. 4. However, outer leads 414a of the lower semiconductor package 400a may have a different shape from the outer leads 314a shown in FIG. 4. The outer leads 414b of the upper semiconductor package 400a may correspond to the outer leads 314b shown in FIG. 4.

In particular, while the outer leads 314b of the upper semiconductor package 300b may still extend form the inner leads 102 of the upper semiconductor package 300b, the edge portions of the outer leads 414a may be formed to be parallel to the direction along which the outer leads 414b extend. For example, the outer leads 414a may linearly extend from inner leads 102 of the lower semiconductor package 400a, be bent upward, and be bent once more to be parallel with the outer leads 414b. In FIG. 4, it is shown that the edge portions of the outer leads 414a are bent toward an encapsulant 112 of the upper semiconductor package 400b; however, these edge portions of the outer leads 314b may also be bent away from the upper semiconductor package 400b. Also, it will be obvious that the outer leads 414a do not need to be formed at a right angle as shown in FIG. 5. As with the previous embodiments, the outer leads 314a may also be soldered to, and hence electrically connected to, the outer leads 314b.

In the stacked semiconductor package 400, the contact areas between the outer leads 414a and 414b may be increased as compared to the stacked semiconductor package 300 shown in FIG. 4. Thus, the stacked semiconductor package 400 may have the same advantages as the stacked semiconductor package 300 shown in FIG. 4, but with a higher electrical connection reliability.

In a modification of the present embodiment, the lower and upper semiconductor packages 400a and 400b may include the intermediate members 120 of the lower and upper semiconductor packages 100a′ and 100b′ shown in FIG. 2.

FIG. 6 is a cross-sectional view of a stacked semiconductor package 500 according to another embodiment of the present invention. The stacked semiconductor package 500 is similar to the stacked semiconductor packages 300 except for the shapes and connection method of the outer leads. Thus, repeated descriptions of similar elements present in both embodiments will be omitted so that the differences between the two embodiments can be more clearly described.

Referring to FIG. 6, the stacked semiconductor package 500 includes an upper semiconductor package 500b and a lower semiconductor package 500a, which are sequentially stacked. The lower and upper semiconductor packages 500a and 500b may respectively correspond to the lower and upper semiconductor packages 300a and 300b shown in FIG. 4. However, the outer leads 514a and 514b may have a different shape from the outer leads 314a and 314b shown in FIG. 4.

The outer leads 514b of the upper semiconductor package 500b may be formed upward like the outer leads 514a of the lower semiconductor package 500a. However, the outer leads 514a and 514b may be formed upward at different angles so as to contact each other. For example, an angle of the outer leads 514a with respect to an encapsulant 112 of the lower semiconductor package 500a may be smaller than an angle of the outer leads 514b with respect to an encapsulant 112 of the upper semiconductor package 500b. Thus, the outer leads 514a and 514b may contact each other and be electrically connected to each other by, for example, solder bonding.

In a modification of the present embodiment, the lower and upper semiconductor packages 500a and 500b may include the intermediate members 120 of the lower and upper semiconductor packages 100a′ and 100b′ shown in FIG. 2.

Referring back to FIG. 1, a method of manufacturing the semiconductor package 100 may include forming the upper semiconductor package 100b such that it includes a semiconductor chip 108, a plurality of inner leads 102 electrically connected to the semiconductor chip, and a encapsulant 112 covering or encapsulating the semiconductor chip 108 and inner leads 102. The method further includes forming the lower semiconductor package 100a such that it includes a semiconductor chip 108, a plurality of inner leads 102 electrically connected to the semiconductor chip 108, a encapsulant 112 covering or encapsulating the semiconductor chip 108 and inner leads 102, and a plurality of outer leads 114a extending from the inner leads 102. Next, the outer leads 114a of the lower semiconductor package 100a may be bent in an upward manner so that when the upper semiconductor package 100b is stacked on the lower semiconductor package 100a, the outer leads 114a may be electrically connected to the inner leads of the upper semiconductor package 100b. After the outer leads 114a of the lower semiconductor package 100a are bent, the upper semiconductor package 100b may be stacked on the lower semiconductor package 100a. The manufacturing method then includes electrically connecting the outer leads 114a of the lower semiconductor package 100a to the inner leads 102 of the upper semiconductor package 100b.

As shown in FIG. 1, the outer leads 114a of the lower semiconductor package 100a may be directly connected to the sidewalls of the inner leads 102 of the upper semiconductor package 100b. This connection may further include solder bonding the outer leads 114a of the lower semiconductor package 100a to the sidewalls of the inner leads 102 of the upper semiconductor package 100b. However, other methods of electrically connecting these leads is also contemplated.

Similar methods may be used to manufacture the embodiments shown in FIGS. 2-6. Because these methods comprise similar steps to the method set out above, descriptions of these similar steps will be omitted. However, as shown in FIGS. 4-6, the upper semiconductor package 100b may also include outer leads 314b, 414b, and 515b extending from the inner leads 102 of the upper semiconductor package 100b, where the outer leads 314a, 414a, and 515a of the lower semiconductor package 100a are electrically connected to the outer leads 314b, 414b, and 515b of the upper semiconductor package 100b.

While the present invention has been particularly shown and described with reference to exemplary embodiments thereof, it will be understood by those of ordinary skill in the art that various changes in form and details may be made therein without departing from the spirit and scope of the present invention as defined by the following claims,

What is claimed is:

1. A semiconductor package comprising:
an upper semiconductor package including:
a semiconductor chip,
a plurality of inner leads electrically connected to the semiconductor chip, and
an encapsulant covering the semiconductor chip and the inner leads; and
a lower semiconductor package sequentially stacked under the upper semiconductor package, the lower semiconductor package including:
a semiconductor chip,
a plurality of inner leads electrically connected to the semiconductor chip,
a encapsulant covering the semiconductor chip and the inner leads, and a plurality of outer leads extending outside the encapsulant from the inner leads of the lower semiconductor package and electrically connected to the inner leads of the upper semiconductor package.

2. The semiconductor package of claim 1, wherein at least a portion of a bottom surface of each of the plurality of inner leads of the upper and lower semiconductor packages is exposed from the encapsulant.

3. The semiconductor package of claim 1, wherein the bottom surfaces of the inner leads of the upper semiconductor package are placed on an upper surface of the encapsulant of the lower semiconductor package.

4. The semiconductor package of claim 1, wherein the outer leads of the lower semiconductor package are bent upward to electrically connect with the inner leads of the upper semiconductor package.

5. The semiconductor package of claim 4, wherein edge portions of the outer leads of the lower semiconductor package are electrically connected to sidewalls of the inner leads of the upper semiconductor package.

6. The semiconductor package of claim 4, wherein edge portions of the outer leads of the lower semiconductor package are electrically connected to the bottom surfaces of the inner leads of the upper semiconductor package.

7. The semiconductor package of claim 6, wherein a portion of the encapsulant under the edge portions of the outer leads of the lower semiconductor package is recessed.

8. The semiconductor package of claim 1, wherein the outer leads of the lower semiconductor package are soldered to the inner leads of the upper semiconductor package.

9. The semiconductor package of claim 1, wherein the inner leads of the upper and lower semiconductor packages include notches or holes.

10. The semiconductor package of claim 9, wherein the notches or holes are filled with a portion of the encapsulant to improve a bond strength between the inner leads and the encapsulant.

11. The semiconductor package of claim 1, wherein the upper and lower semiconductor packages further comprise nonconductive intermediate members interposed between the inner leads and the encapsulant.

12. The semiconductor package of claim 1, wherein the upper and lower semiconductor packages further comprise chip mounting pads on which the semiconductor chips are mounted, and wherein bottom surfaces of the chip mounting pads are exposed from the encapsulant.

13. A stacked semiconductor package comprising:
upper and lower semiconductor packages sequentially stacked,
wherein each of the upper and lower semiconductor packages comprises:
a semiconductor chip;
a plurality of inner leads comprising upper surfaces and bottom surfaces and electrically connected to the semiconductor chip;
a encapsulant covering the semiconductor chip and the inner leads; and
a plurality of outer leads connected to the inner leads and extending outside the encapsulant, wherein the upper surfaces of the upper and lower semiconductor packages are fixed to the encapsulant, portions of the bottom surfaces are exposed from the encapsulant, and the outer leads of the lower semiconductor package are formed toward the upper semiconductor package to be electrically connected to the outer leads of the upper semiconductor package.

14. The stacked semiconductor package of claim 13, wherein the bottom surfaces of the inner leads of the upper semiconductor package are placed on an upper surface of the encapsulant of the lower semiconductor package.

15. The stacked semiconductor package of claim 13, wherein the outer leads of the lower semiconductor package are bent upward to electrically connect with the outer leads of the upper semiconductor package.

16. The stacked semiconductor package of claim 15, wherein edge portions of the outer leads of the lower semiconductor package are electrically connected to the outer leads of the upper semiconductor package.

17. The stacked semiconductor package of claim 13, wherein the outer leads of the upper semiconductor package linearly extend from sidewalls of the inner leads of the upper semiconductor package.

18. The stacked semiconductor package of claim 17, wherein the edge portions of the outer leads of the lower semiconductor package are formed to be parallel with a direction along which the outer leads of the upper semiconductor package extend.

19. The stacked semiconductor package of claim 17, wherein the edge portions of the outer leads of the lower semiconductor package are perpendicular to a direction along which the outer leads of the upper semiconductor package extend.

20. The stacked semiconductor package of claim 15, wherein the outer leads of the upper semiconductor package are formed to extend upward from the inner leads of the upper semiconductor package at a first angle.

21. The stacked semiconductor package of claim 20, wherein the outer leads of the lower semiconductor package are formed to extend upward from the inner leads of the lower semiconductor package at a second angle, the second angle being smaller than the first angle with respect to the encapsulant.

22. The stacked semiconductor package of claim 13, wherein the inner leads of the upper and lower semiconductor packages include notches or holes that are filled with a portion of the encapsulant to improve a bond strength between the inner leads and the encapsulant.

23. The stacked semiconductor package of claim 13, wherein the upper and lower semiconductor packages further comprise nonconductive intermediate members interposed between the inner leads and the encapsulant.

24. The stacked semiconductor package of claim 13, wherein the outer leads of the upper semiconductor package are physically connected to the inner leads of the upper semiconductor package, and the inner leads of the lower semiconductor package are physically connected to the outer leads.

25. A method of manufacturing a semiconductor package, the method comprising:
providing an upper semiconductor package including a semiconductor chip, a plurality of inner leads electrically connected to the semiconductor chip, and a encapsulant covering the semiconductor chip and inner leads;
providing a lower semiconductor package including a semiconductor chip, a plurality of inner leads electrically connected to the semiconductor chip, a encapsulant covering the semiconductor chip and inner leads, and a plurality of outer leads extending from the inner leads;
bending the outer leads of the lower semiconductor package in an upward manner;
stacking the upper semiconductor package on the lower semiconductor package; and
electrically connecting the outer leads of the lower semiconductor package to the inner leads of the upper semiconductor package.

26. The method of claim 25, wherein electrically connecting the outer leads of the lower semiconductor package to the inner leads of the upper semiconductor package includes solder bonding the outer leads of the lower semiconductor package to the inner leads of the upper semiconductor package.

27. The method of claim 25, wherein the upper semiconductor package further comprises outer leads connected to the inner leads and extending outside the encapsulant, and wherein electrically connecting the outer leads of the lower semiconductor package to the inner leads of the upper semiconductor package includes electrically connecting the outer leads of the lower semiconductor package to the outer leads of the upper semiconductor package.
